(19) United States
(12) Patent Application Publication
(10) Pub. No.: US 2008/0293205 A1
(43) Pub. Date: Nov. 27, 2008

(54) METHOD OF FORMING METAL SILICIDE LAYER, AND METHOD OF MANUFACTURING SEMICONDUCTOR DEVICE USING THE SAME

(76) Inventors: Oh-Kyum KWON, Suwon-si (KR); Bum-Seok KIM, Seoul (KR); Geun-Sook PARK, Suwon-si (KR); Joon-Suk OH, Seoul (KR); Hye-Young PARK, Seoul (KR); Min-Jun CHOI, Suwon-si (KR)

Correspondence Address: F. CHAU & ASSOCIATES, LLC, 130 WOODBURY ROAD, WOODBURY, NY, 11797, US

(21) Appl. No.: 12/125,224

(22) Filed: May 22, 2008

(30) Foreign Application Priority Data
May 23, 2007 (KR) 10-2007-0050377

(51) Int. Cl. H01L 21/336; H01L 21/44

(52) U.S. Cl. 438/293; 438/660; 257/E21.476; 257/E21.409

(57) ABSTRACT

A method of forming a metal silicide layer includes sequentially forming a metal layer and a first capping layer on a substrate, performing a first heat treatment on the substrate to cause the substrate to react to the metal layer, removing the first, capping layer and an unreacted metal layer, forming a second capping layer on the substrate, and performing a second heat treatment on the substrate to form a metal silicide layer on the substrate.

### CROSS REFERENCE TO RELATED APPLICATION

This application claims priority from Korean Patent Application No. 10-2007-0050377 filed on May 23, 2007 in the Korean Intellectual Property Office, the disclosure of which is incorporated herein by reference in its entirety.

### BACKGROUND OF THE INVENTION

1. Technical Field of the Invention

The present disclosure relates to a method of forming a metal silicide layer, and a method of manufacturing a semiconductor device using the same.

2. Discussion of Related Art

A Schottky barrier means an energy barrier that is formed on a surface of a semiconductor due to contact between metal and a semiconductor. A diode, which is formed using the Schottky barrier, is called a Schottky diode. The Schottky diode uses majority carriers as conductive components, and minority carriers are hardly implanted into the Schottky diode. For this reason, minority carriers are not accumulated in the Schottky diode. Accordingly, the Schottky diode has a short switching time and is suitable for a high-speed switching operation. Further, the Schottky diode has a low threshold voltage and low series resistance. Further, because the Schottky diode has the excellent thermal conductivity of metal, the Schottky diode has excellent heat radiating properties.

In general, the Schottky diode is produced by forming a metal silicide layer on a first conductive type, for example, N-type, semiconductor substrate.

If normal bias is applied to the Schottky diode, for example, a positive voltage is applied to an anode (metal silicide layer), and a ground voltage is applied to a cathode, a plurality of electrons moves from the semiconductor substrate to the metal layer. In contrast, if a reverse bias is applied to the Schottky diode, for example, a negative voltage is applied to an anode (metal silicide layer), and a ground voltage is applied to a cathode, electrons hardly move.

Even while the reverse bias is applied to the Schottky diode, however, a few electrons actually move. That is, a reverse leakage current may be generated. Various factors have an effect on the amount of the reverse leakage current. In particular, the morphology of the metal silicide layer considerably affects the value of the reverse leakage current. Accordingly, the improvement of the morphology of the metal silicide layer needs to be researched to reduce the reverse leakage current.

### SUMMARY OF THE INVENTION

Exemplary embodiments of the present invention provide a method of forming a metal silicide layer that improves the morphology of a metal silicide layer.

Exemplary embodiments of the present invention provide a method of manufacturing a semiconductor device using the method of manufacturing the metal silicide layer.

In an exemplary embodiment, the present invention provides a method of forming a metal silicide layer, the method comprising: sequentially forming a metal layer and a first capping layer on a substrate, performing a first heat treatment on the substrate to allow the substrate to react to the metal layer, removing the first capping layer and an unreacted metal layer, forming a second capping layer on the substrate, and performing a second heat treatment on the substrate to form a metal silicide layer on the substrate.

In an exemplary embodiment, the present invention provides a method of manufacturing a semiconductor device, the method comprising: forming wells in a substrate, sequentially forming a metal layer and a first capping layer on the substrate, performing a first heat treatment on the substrate to allow the substrate to react to the metal layer, removing the first capping layer and an unreacted metal layer, forming a second, capping layer on the substrate, and performing a second heat treatment on the substrate to form a metal silicide layer on the wells.

According to an exemplary embodiment, the present invention provides a method of manufacturing a semiconductor device, the method comprising: defining a first region and a second region in a substrate, the second, region surrounding the first region, forming a first conductive-type well in the first and second regions, sequentially forming a metal layer and a first capping layer on the first and second regions, performing a first heat treatment on the substrate to allow the first and second regions to react to metal layer, removing the first capping layer and an unreacted metal layer, forming a second capping layer on the first and second regions, and performing a second heat treatment on the substrate to form a metal silicide layer on the first and second regions.

An exemplary embodiment of the present invention provides a method of manufacturing a semiconductor device, the method comprising: defining a diode-forming region and a transistor-forming region in a substrate, forming first and second wells in the diode-forming region and the transistor-forming region, respectively, forming an MOS transistor in the transistor-forming region, sequentially forming a metal layer and a first capping layer on the first well and the MOS transistor, performing a first heat treatment on the substrate to allow the first well and the MOS transistor to react to the metal layer, removing the first capping layer and an unreacted metal layer, farming a second capping layer on the first well and the MOS transistor, and performing a second heat treatment on the substrate to form a metal silicide layer on the first well and the MOS transistor.

### BRIEF DESCRIPTION OF THE DRAWINGS

Exemplary embodiments of the present invention will be understood in more detail from the following descriptions taken in conjunction with the attached drawings, in which:

FIGS. 1 to 4 are views illustrating a method of forming a metal silicide layer according to an exemplary embodiment of the present invention;

FIGS. 5 to 10 are views illustrating a method of manufacturing a semiconductor device according to an exemplary embodiment of the present invention;

FIGS. 11 to 15 are views illustrating a method of-manufacturing a semiconductor device according to an exemplary embodiment of the present invention;

FIG. 16A is a photograph showing the morphology of a metal silicide film that is completely formed without a second capping film before a second heat treatment;

FIG. 16B is a photograph showing the morphology of the metal silicide film that is completely formed with the second capping film before the second heat treatment; and

FIG. 17 is a graph showing results of reverse leakage current of a Schottky diode that is completely formed without the second capping film before the second heat treatment, and reverse leakage current of a Schottky diode that is completely formed with the second capping film before the second heat treatment.

### DETAILED DESCRIPTION OF EXEMPLARY EMBODIMENTS

Advantages and features of the present invention and methods of accomplishing the same may be understood more readily by reference to the following detailed description of exemplary embodiments and the accompanying drawings. The present invention may, however, be embodied in many different forms and should not be construed as being limited to the exemplary embodiments set forth herein. Rather, these exemplary embodiments are provided so that this disclosure will be thorough and complete and will fully convey the concept of the present invention to those of ordinary skill in the art, and the present invention will be defined only by the appended claims. Like reference numerals refer to like elements throughout the specification.

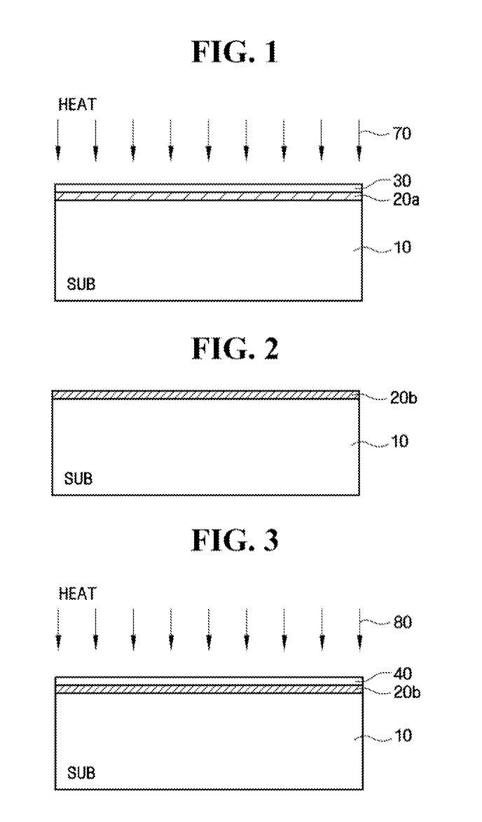

FIGS. 1 to 4 are views illustrating a method of forming a metal silicide layer according to an exemplary embodiment of the invention.

Referring to FIG. 1, a metal layer 20a and a first capping layer 30 are sequentially formed on a substrate 10.

More specifically, a silicon substrate, a SOI (Silicon On Insulator) substrate, a silicon germanium substrate, or the like may be used as the substrate 10.

The metal layer 20a may be made of at least one of, for example, Co, Ni, and Ti. The metal layer made of Co will be exemplified in this exemplary embodiment of the present invention. The metal layer 20a may be formed using a PVD (Physical Vapor Deposition) method, a CVD (Chemical Vapor Deposition) method, an ALD (Atomic Layer Deposition) method, or the like. The thickness of the metal layer 20a should be determined in consideration of the thickness of silicon, which is to be removed under the metal layer 20a in subsequent first and second beat treatments. For example, although not shown in the drawings, if junction regions used as a source and a drain exist under the metal layer 20a, the thickness of the metal layer 20a should be determined so that the junction regions are not completely removed.

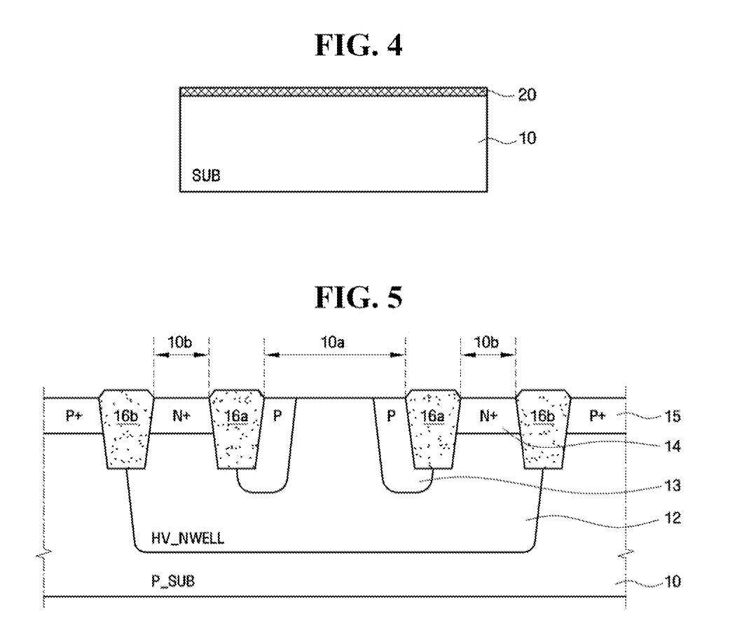

The first capping layer 30 is formed on the metal layer 20a, and used to improve the morphology of a metal silicide layer, shown at 20 in FIG. 4. The first capping layer 30 may be applied to have a thickness of, for example, 10 Å, or more. The first capping layer 30 may be made of at least one of, for example, TiN, Si ON, SiN, and SiO₂. The first capping layer 30 made of TiN will be exemplified in this exemplary embodiment of the present invention.

Subsequently, a first heat treatment 70 is performed on the substrate 10 to allow the substrate 10 to react to the metal layer 20a.

In the first heat treatment 70, the substrate is heated at a temperature in the range of about 300 to 600° C., more preferably, about 400 to 500° C., for about 30 seconds. Further, a RTA (Rapid Thermal Annealing) method may be used to perform the first heat treatment 70.

The substrate 10 reacts to the metal layer 20a by the above-mentioned first heat treatment 70, and a pre-metal silicide layer, shown at 20b in FIG. 2, is formed. When Co is used as the metal layer, the pre-metal silicide layer 20b may be, for example, Co₂Si or CoSi.

Referring to FIG. 2, the first capping layer 30 and an unreacted metal layer are removed. The first capping layer 30 and the unreacted metal layer may be separately removed, or the first capping layer 30 and the unreacted metal layer may be simultaneously removed. For example, if the metal layer 20a is made of Co and the first capping layer 30 is made of TiN, the first capping layer 30 and the unreacted metal layer can be simultaneously removed by sulfuric acid.

Referring to FIG. 3, a second capping layer 40 is formed on the pre-metal silicide layer 20b.

The second capping layer 40 is formed on the pre-metal silicide layer 20b, and used to improve the morphology of a metal silicide layer, shown at 20 in FIG. 4, that is to be completely formed by a second heat treatment 80. More specifically, because two capping layers 30 and 40 are used, it is possible to significantly improve the morphology of the metal silicide layer 20 as compared to when only one capping layer 30 is used. The second capping layer 40 may be applied to have a thickness of, for example, 10 Å or more. The second capping layer 40 may be made of at least one of, for example, TiN, SiON, SiN, and SiO₂. The second capping layer 40 made of TiN will be exemplified in this exemplary embodiment, of the present invention.

Then, as shown in FIG. 3, a second heat treatment 80 is performed on the substrate.

The temperature at which the second heat treatment 80 is performed is higher than the temperature at which the first heat treatment 70 is performed. For example, the second heat treatment 80 is performed on the substrate 10 at a temperature in the range of about 700 to 1000° C., preferably, about 750 to 800° C., for about 30 seconds. A RTA (Rapid Thermal Annealing) method may be used to perform the second heat treatment 80.

The pre-metal silicide layer 20b is changed into the metal silicide layer, shown at 20 in FIG. 4, by the second heat treatment. That is, Co₂Si or CoSi is changed into CoSi₂.

Referring to FIG. 4, the second capping layer 40 is removed. For example, the second capping layer 40 can be removed by sulfuric acid.

FIGS. 5 to 10 are views illustrating a method of manufacturing a semiconductor device according to an exemplary embodiment of the present invention. A method of manufacturing a semiconductor device illustrated in FIGS. 5 to 10 uses the method of forming the metal silicide layer illustrated in FIGS. 1 to 4. Although the method of manufacturing a Schottky diode is exemplified in FIGS. 5 to 10, the present invention is not limited thereto.

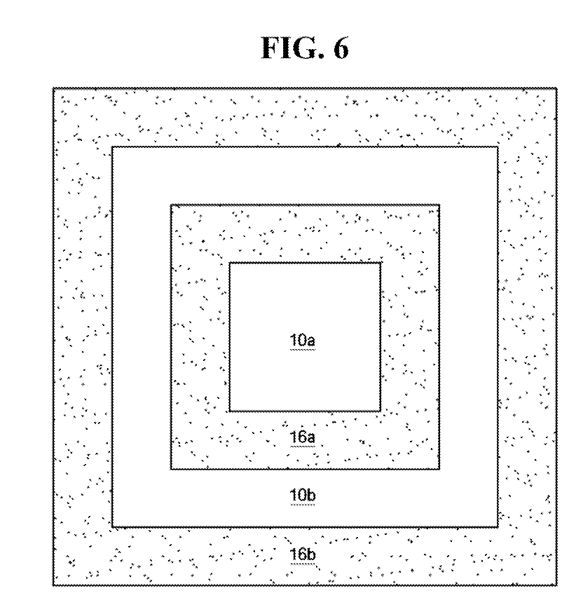

First, referring to FIGS. 5 and 6, isolating elements 16a and 16b are formed in the substrate 10 to define a first region 10a and a second, region 10b, As shown in FIG. 6, the second region 10b may be formed to surround the first region 10a. The first region 10a corresponds to an anode of a Schottky diode, and the second region 10b corresponds to a cathode of the Schottky diode.

Subsequently, a first conductive type, for example, an N-type, well 12 is formed in the first and second regions 10a and 10b. In this case, the well 12 may be used in a device using, for example, a high voltage, and may have a significantly low concentration as compared to a device using a low voltage.

Then, a second conductive type, for example, a P-type, well 13 is formed in the first region 10a along a boundary between the first and second regions 10a and 10b. When a reverse bias is applied to the Schottky diode, the well 13 prevents a leakage current from flowing to the adjacent isolating element 16a in the metal silicide layer shown at 20 in FIG. 10. The second conductive type well 13 and the first conductive type well 12 form a PN junction diode, and the PN junction diode prevents the leakage current from flowing. Because the PN junction diode prevents the leakage current from flowing, the second conductive type well 13 is referred to as a guardring.

Subsequently, junction regions 14 and 15 are formed in the substrate 10. The junction region 14 is the same type as the well 12, that is, the second conductive type region. The junction region 15 is the same type as the substrate 10, that is, the first conductive type region. The junction regions 14 and 15 serve as ohmic contacts.

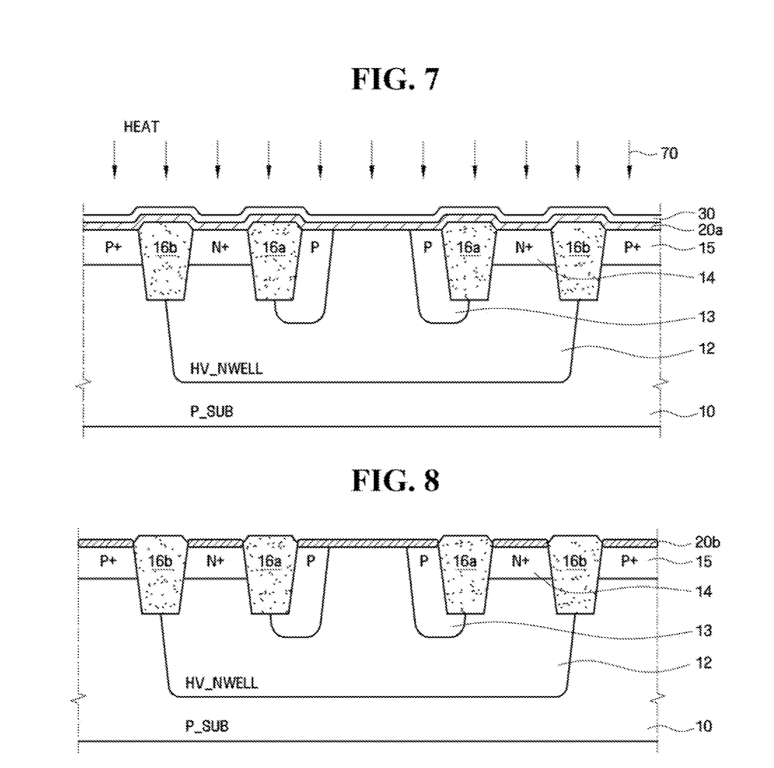

Referring to FIG. 7, the metal layer 20a and the first capping layer 30 are sequentially formed on the first and second regions 10a and 10b. The metal layer 20a may be made of at least one of, for example, Co, Ni, and Ti. A metal layer made of Co will be exemplified in this exemplary embodiment of the present invention. The first capping layer 30 may be made of at least one of, for example, TiN, SiON, SiN, and SiO₂. A first capping layer made of TiN will be exemplified in this exemplary embodiment of the present invention.

Subsequently, a first heat treatment 70 is performed on the substrate 10 to allow the first and second regions 10a and 10b to react to the metal layer 20a. In the first heat treatment 70, the substrate is heated at a temperature in the range of about 300 to 600° C., preferably, about 400 to 500° C., for about 30 seconds. A RTA (Rapid Thermal Annealing) method may be used to perform the first heat treatment 70. The first and second regions 10a and 10b react to the metal layer 20a by the above-mentioned first heat treatment 70, and a pre-metal silicide layer, shown at 20b in FIG. 8, is formed. When Co is used as the metal layer, the pre-metal silicide layer 20b may be, for example, Co₂Si or CoSi.

Referring to FIG. 8, the first capping layer 30 and an unreacted metal layer are removed.

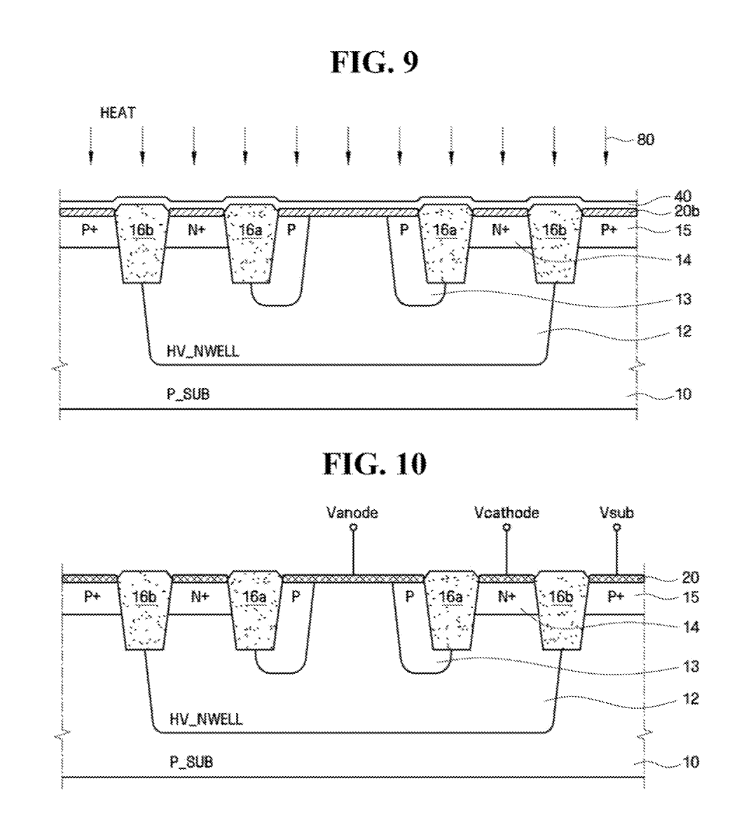

Referring to FIG. 9, a second capping layer 40 is formed on the pre-metal silicide layer 20b. The second capping layer 40 may be made of at least one of, for example, TiN, SiON, SiN, and SiO₂. A second capping layer made of TiN will be exemplified in this exemplary embodiment of the present invention.

Then, a second heat treatment 80 is performed on the substrate. The temperature at which the second heat treatment 80 is performed is higher than the temperature at which the first heat treatment 70 is performed. For example, the second heat treatment 80 is performed on the substrate 10 at a temperature in the range of about 700 to 1000° C., preferably, about 750 to 800° C., for about 30 seconds. The pre-metal silicide layer 20b is changed into the metal silicide layer, shown at 20 in FIG. 10, by the second heat treatment. That is, Co₂Si or CoSi is changed into CoSi₂.

Referring to FIG. 10, the second capping layer 40 is removed.

The metal silicide layer 20 comes in contact with the substrate 10, so that a Schottky diode is completely formed. Specifically, an anode voltage Vanode is applied to the metal silicide layer 20 formed on the first region 10a, and a cathode voltage Vcathode is applied to the metal silicide layer 20 formed on the second region 10b.

A substrate voltage Vsub is applied to the metal silicide layer 20 formed on the junction region 15.

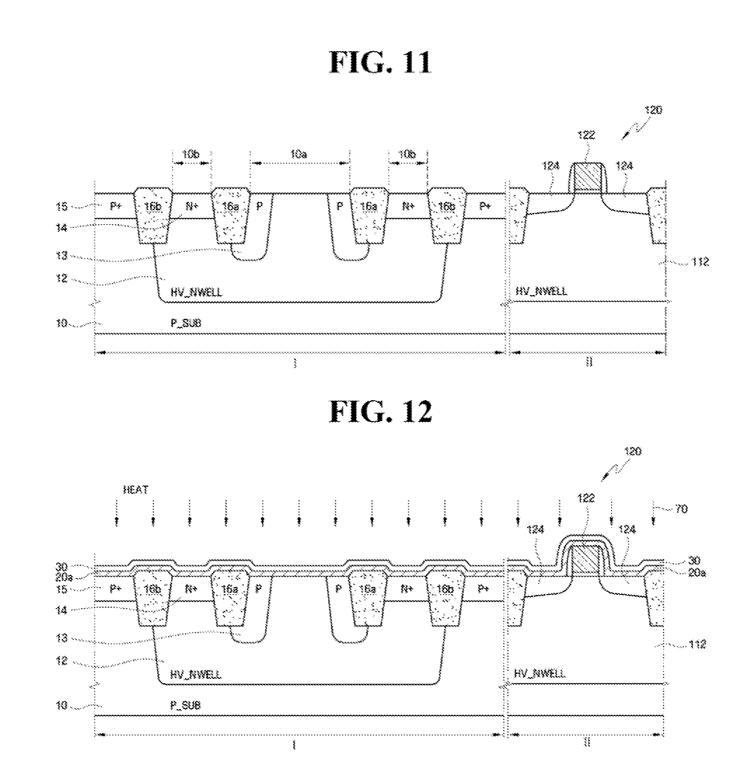

FIGS. 11 to 15 are views illustrating a method of manufacturing a semiconductor device according to an exemplary embodiment of the present invention. A method, which includes the method illustrated in FIGS. 5 to 10 and a method in the related art, will be described with reference to FIGS. 11 to 15.

Referring to FIG. 11, first, a diode-forming region I and a transistor-forming region II are formed in the substrate 10.

Then, first and second wells 12 and 112 are formed in the diode-forming region I and the transistor-forming region II, respectively.

Subsequently, an MOS transistor 120 is formed in the transistor-forming region II. The MOS transistor 120 may be a high-voltage driving transistor, and includes a gate 122 and source and drain regions 124 provided on both sides of the gate 122. The source and drain regions 124 are not shown in detail in FIG. 11. As long as the source and drain regions are suitable for high-voltage driving, however, any structure, such as an MIDDD (Mask Islanded Double Diffused Drain) structure, an LDD (Lightly Diffused Drain) structure, an MLDD) (Mask LDD) structure, or an LDMOS (Lateral Double-diffused MOS) structure, can be used as the source and drain regions.

Referring to FIG. 12, a metal layer 20a and a first capping layer 30 are formed on the first well 12 and the MOS transistor 120.

Then, a first heat treatment 70 is performed on the substrate 10 to allow the first well 12 and the MOS transistor 120 to react to the metal layer 20a.

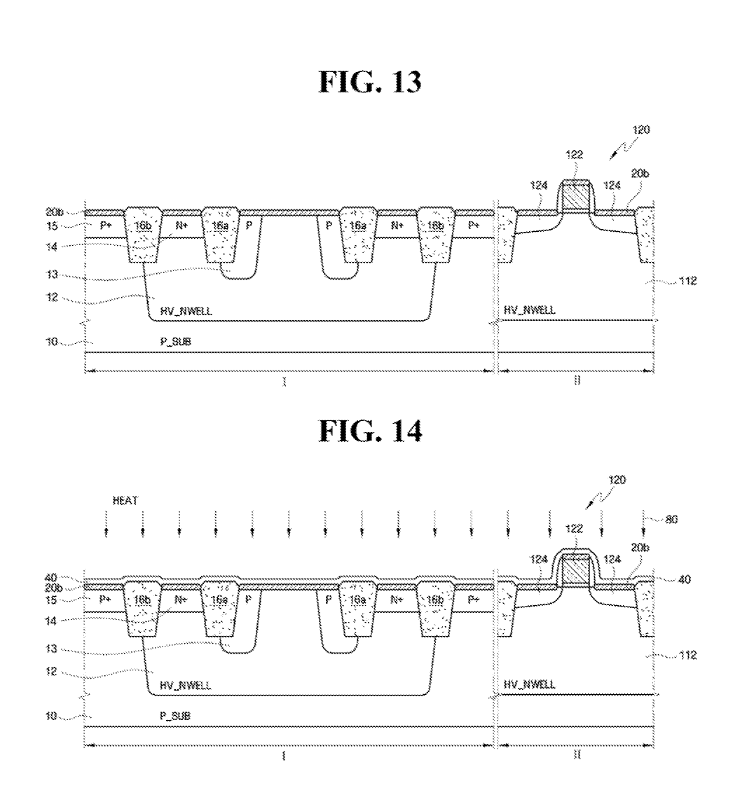

Referring to FIG. 13, the first capping layer 30 and an unreacted metal layer are removed.

Referring to FIG. 14, a second capping layer 40 is formed on the first well 12 and the MOS transistor 120.

Subsequently, the second heat treatment 80 is performed on the substrate 10 to form a metal silicide layer 20 on the first well 12 and the MOS transistor 120. The metal silicide layer 20 may be formed as well on the gate 122 of the MOS transistor 120 or the source and drain regions 124.

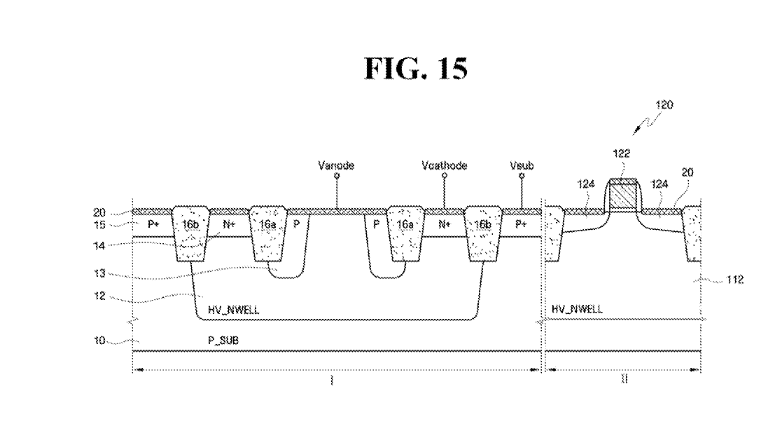

Referring to FIG. 15, the second capping layer 40 is removed.

Details about the present invention will be described with reference to the following experimental examples. Because other details omitted below can be derived by those of ordinary skill in the art, the descriptions thereof will be omitted.

In the case of a comparative group, wells were formed in a substrate, a metal layer (Co) and a first capping layer (TiN) were formed on the substrate, a first heat treatment involving heating at a temperature of 400° C. for 30 seconds was performed, the first capping layer and the unreacted metal layer were removed, and a second heat treatment involving heating at a temperature of 750° C. for 30 seconds was performed to form a metal silicide layer. Accordingly, a Schottky diode was completely formed.

Meanwhile, in the case of an experimental group, wells were formed in a substrate, a metal layer (Co) and a first capping layer (TiN) were formed on the substrate, a first heat treatment involving heating at a temperature of 400° C. for 30 seconds was performed, the first capping layer and the unreacted metal layer were removed, a second capping layer (TiN) was formed on the substrate, and a second heat treatment involving heating at a temperature of 750° C. for 30 seconds was performed to form a metal silicide layer. Accordingly, a Schottky diode was completely formed.

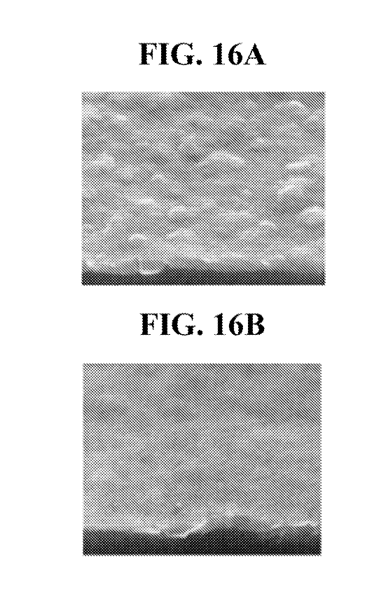

Subsequently, the surfaces of the metal silicide layers of a plurality of Schottky diodes belonging to the comparative group, and the surfaces of the metal silicide layers of a plurality of Schottky diodes belonging to the experimental group were observed. Results of the observation are shown in FIGS. 16A and 168.

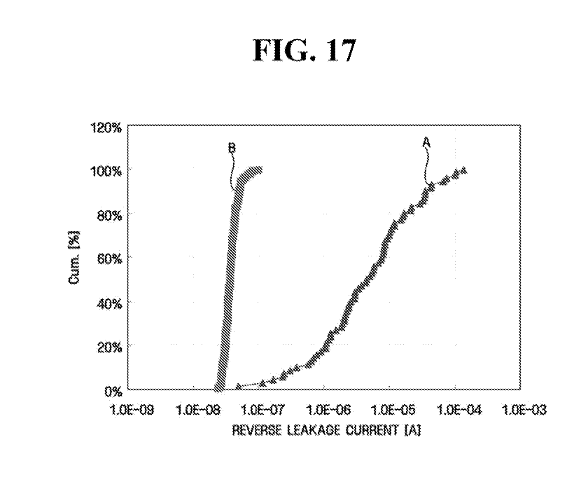

The reverse leakage current of the plurality of Schottky diodes belonging to the comparative group is measured, and the reverse leakage current of the plurality of Schottky diodes belonging to the experimental group is measured. A voltage of about −20 V is applied to the anode of each of the Schottky diodes, and a voltage of about 0 V is applied to the cathode thereof. Results of the measurement are shown in FIG. 17.

It is understood that the morphology of die metal silicide layer shown in FIG. 16B is clearly improved as compared to the morphology of the metal silicide layer shown in FIG. 16A.

Referring to FIG. 17, the x axis represents a reverse leakage current (A), and the y axis represents the accumulation ratio (%) of the Schottky diodes. It is understood that the maximum reverse leakage current of the Schottky diodes belonging to the comparative group A is 1000 times as large as the minimum reverse leakage current of the Schottky diodes belonging to the experimental group B. It is understood that the maximum reverse leakage current of the Schottky diodes belonging to the experimental group B is less than the minimum reverse leakage current of the Schottky diodes belonging to the comparative group A by 1000 times or less. It is also understood that in any event the reverse leakage current of the Schottky diodes belonging to the experimental group B is smaller than the reverse leakage current of the Schottky diodes belonging to the comparative group A.

Although the present invention has been described in connection with the exemplary embodiments of the invention, it will be apparent to those of ordinary skill in the art that various modifications and changes may be made thereto without departing from the scope and spirit of the invention. Therefore, it should be understood that the above exemplary embodiments are not limitative, but illustrative in all aspects.

It is possible to improve the morphology of a metal silicide layer by using the above-described exemplary method of forming a metal silicide layer. In addition, if a Schottky diode is formed by using the exemplary method of forming a metal silicide layer, it is possible to significantly reduce the reverse leakage current of the Schottky diode.

What is claimed is:

1. A method of forming a metal silicide layer, the method comprising:
sequentially forming a metal layer and a first capping layer on the metal layer on a substrate;
performing a first heat treatment on the substrate to cause the substrate to react to the metal layer;
removing the first capping layer and an unreacted metal layer;
forming a second capping layer on the substrate; and
performing a second heat treatment on the substrate to form a metal silicide layer on the substrate.

2. The method of claim 1, wherein the metal layer is made of at least one of Co, Ni, and Ti.

3. The method of claim 1, wherein the first capping layer is made of at least one of TiN, SiON, SiN, and SiO₂.

4. The method of claim 1, wherein a temperature at which the second heat treatment is performed is higher than a temperature at which the first heat treatment is performed.

5. A method of manufacturing a semiconductor device, the method comprising:
forming wells in a substrate,
sequentially forming a metal layer and a first capping layer on the metal layer on the substrate;
performing a first heat treatment on the substrate to cause the substrate to react to the metal layer;
removing the first capping layer and an unreacted metal layer;
forming a second capping layer on the substrate; and
performing a second heat treatment on the substrate to form a metal silicide layer on the wells in the substrate.

6. The method of claim 5, wherein the metal layer is made of at least one of Co, Ni, and Ti.

7. The method of claim 5, wherein the first capping layer is made of at least one of TiN, SiON, SiN, and SiO₂.

8. The method of claim 5, wherein a temperature at which the second heat treatment is performed is higher than a temperature at which the first heat treatment is performed.

9. A method of manufacturing a semiconductor device, the method comprising:
defining a first region and a second region in a substrate, the second region surrounding the first region;
forming a first conductive-type well in the first and second regions;
sequentially forming a metal layer and a first capping layer on the metal layer on the first and second regions;
performing a first heat treatment on the substrate to cause the first and second regions to react to metal layer;
removing the first capping layer and an unreacted metal layer;
forming a second capping layer on the first and second regions; and
performing a second heat treatment on the substrate to form a metal silicide layer on the first and second regions.

10. The method of claim 9, wherein the metal layer is made of at least one of Co, Ni, and Ti.

11. The method of claim 9, wherein the first capping layer is made of at least one of TiN, SiON, SiN, and SiO₂.

12. The method of claim 9, wherein a temperature at which the second heat treatment is performed is higher than a temperature at which the first heat treatment is performed.

13. The method, of claim 9, further comprising:
forming a second conductive-type well in the first region along a boundary between the first and second regions, wherein the second conductive type is different from the first conductive type.

14. The method of claim 9, further comprising:
forming a first conductive-type junction region in the second region.

15. A method of manufacturing a semiconductor device, the method comprising:
defining a diode-forming region and a transistor-forming region in a substrate;
forming first and second wells in the diode-forming region and the transistor-forming region, respectively;
forming an MOS transistor in the transistor-forming region;
sequentially forming a metal layer and a first capping layer on the metal layer on the first well and the MOS transistor;
performing a first heat treatment on the substrate to cause the first well and the MOS transistor to react to the metal layer;
removing the first capping layer and an unreacted metal layer;
forming a second capping layer on the first well and on the MOS transistor; and
performing a second heat treatment on the substrate to form a metal silicide layer on the first well and on the MOS transistor.

16. The method of claim 15, wherein the metal layer is made of at least one of Co, Ni, and Ti.

17. The method of claim 15, wherein the first capping layer is made of at least one of TiN, SiON, SiN, and SiO₂.

18. The method of claim 15, wherein a temperature at which the second heat treatment is performed is higher than a temperature at which the first heat treatment is performed.

19. The method of claim 15, wherein the forming of the metal silicide layer on the MOS transistor includes forming a metal silicide layer on a gate and source/drain regions of the MOS transistor.

20. The method of claim 15, wherein the MOS transistor is a high-voltage driving transistor.
